(19) United States
(12) Patent Application Publication
(10) Pub. No.: US 2025/0107257 A1
(43) Pub. Date: Mar. 27, 2025

(54) ELECTRONIC COMPONENT AND EQUIPMENT

(71) Applicant: CANON KABUSHIKI KAISHA, Tokyo (JP)

(72) Inventor: YU KATASE, Kanagawa (JP)

(21) Appl. No.: 18/830,650

(22) Filed: Sep. 11, 2024

(30) Foreign Application Priority Data
Sep. 21, 2023 (JP) 2023-156527

(51) Int. Cl. H01L 27/146; H01L 23/00

(52) U.S. Cl. CPC H10F 39/804; H01L 24/48; H10F 39/811; H01L 2224/48227

(57) ABSTRACT

An electronic component comprising a base, an electronic device including a first surface having a region facing the base and a second surface on an opposite side to the first surface, a support arranged between the electronic device and the base, a conductive wire connecting a first terminal arranged in the second surface and a second terminal arranged in a third surface of the base, and a resin member arranged to cover the conductive wire, is provided. The support includes a fourth surface facing the first surface, a fifth surface on an opposite side to the fourth surface and a side surface. The resin member covers at least part of the side surface, and the support includes a chamfered portion between the side surface and at least one of the fourth principal surface and the fifth principal surface.

### BACKGROUND OF THE INVENTION

### Field of the Invention

The present disclosure relates to an electronic component and equipment.

### Description of the Related Art

Japanese Patent Laid-Open No. 2019-087640 discloses an electronic component in which a detector obtained by stacking a semiconductor layer with a detection region on a support portion supporting the semiconductor layer is accommodated in the base of a package. The semiconductor layer is electrically connected to the internal terminals of the base via bonding wires.

Bonding wires that connect a semiconductor layer to a base are sometimes sealed with a resin to protect the bonding wires. Assume that a side surface of the detector has discontinuous portions such as gaps between the semiconductor layer and the support portion. In this case, when the bonding wires are sealed with a resin, the resin cannot completely permeate the discontinuous portions on the side surface of the detector, and air bubbles are sometimes generated in the resin. In the presence of air bubbles in the resin, when the outside air pressure becomes lower than the air pressure in the air bubbles under an environment in which an electronic component is arranged, the air bubbles may expand and damage the electronic component.

Some embodiments of the present disclosure provide techniques advantageous in suppressing damage to an electronic component.

### SUMMARY OF THE INVENTION

According to some embodiments, an electronic component comprising: a base; an electronic device including a first principal surface having a region facing the base and a second principal surface on an opposite side to the first principal surface; a support member arranged between the electronic device and the base; a conductive wire configured to connect a first terminal arranged in the second principal surface to a second terminal arranged in a third principal surface on which the electronic device of the base is mounted; and a resin member arranged so as to cover the conductive wire, wherein the support member includes a fourth principal surface facing the first principal surface, a fifth principal surface on an opposite side to the fourth principal surface, and a side surface connecting the fourth principal surface to the fifth principal surface, the resin member covers at least part of the side surface, and the support member includes a chamfered portion obtained by chamfering a portion between the side surface and at least one of the fourth principal surface and the fifth principal surface, is provided.

Further features of the present invention will become apparent from the following description of exemplary embodiments (with reference to the attached drawings).

### BRIEF DESCRIPTION OF THE DRAWINGS

FIG. 1A is a plan view showing an example of the arrangement of an electronic component according to this embodiment;

FIG. 1B is a sectional view showing an example of the arrangement of the electronic component according to this embodiment;

FIG. 2 is a sectional view showing the arrangement of a support member of the electronic component in FIG. 1;

FIG. 3 is a sectional view showing a modification of the support member in FIG. 2;

FIG. 4A is a plan view showing an example of the arrangement of an electronic component according to a comparative example;

FIG. 4B is a sectional view showing an example of the arrangement of the electronic component according to the comparative example;

FIGS. 5A and 5B are sectional views showing the arrangement of a support member of the electronic component according to the comparative example;

FIG. 6 is a sectional view showing a modification of the support member in FIG. 2;

FIG. 7 is an enlarged view of the support member in FIG. 6; and

FIG. 8 is a view showing an example of the arrangement of equipment incorporating the electronic component according to this embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

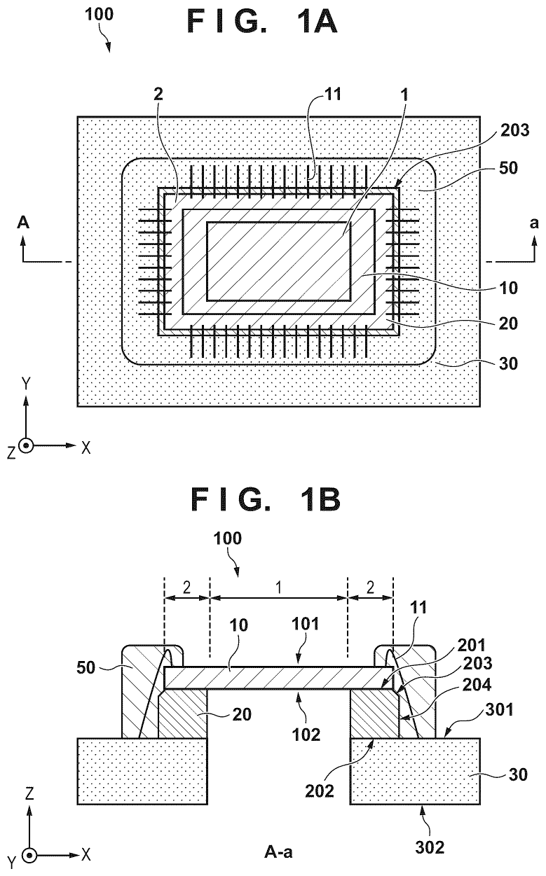

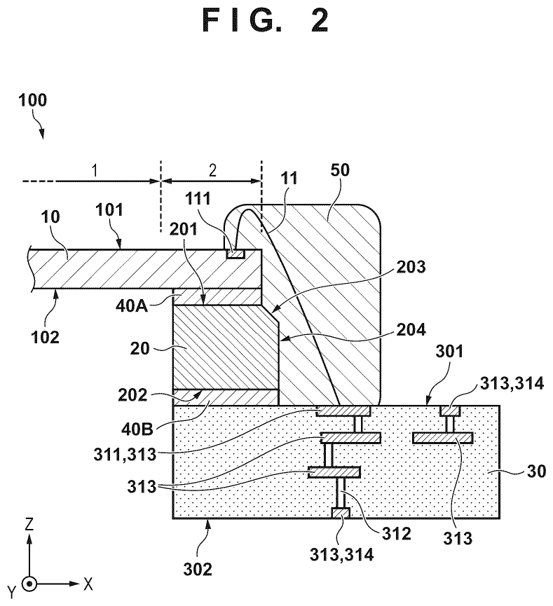

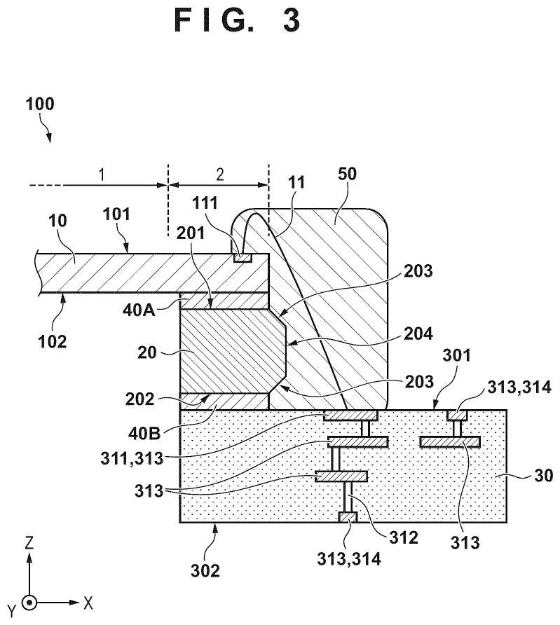

An electronic component according to an embodiment of the present disclosure will be described with reference to FIGS. 1A and 1B to 7. FIGS. 1A and 1B are schematic views showing an example of the arrangement of an electronic component 100 according to this embodiment. FIG. 1A is a plan view showing an example of the arrangement of the electronic component 100. FIG. 1B is a sectional view taken along A-a shown in FIG. 1A. FIGS. 2 and 3 each are an enlarged sectional view of a right portion of the sectional view shown in FIG. 1B. Each drawing shows X, Y, and Z directions. Hereinafter, the X and Y directions each are sometimes referred to as a planar direction of the electronic component 100, and the Z direction is sometimes referred to as the thickness direction of the electronic component 100. The X direction (the Y direction) and the Z direction are directions vertically intersecting each other.

The electronic component 100 includes a base 30, an electronic device 10 having a principal surface 102 having a region facing the base 30 and a principal surface 101 on the opposite side to the principal surface 102, and a support member 20 arranged between the electronic device 10 and the base 30. The base 30 can form a package accommodating the electronic device 10. The support member 20 supports the electronic device 10 between the electronic device 10 and the base 30. The electronic component 100 further includes conductive wires 11 that connect terminals 111 arranged in the principal surface 101 of the electronic device 10 to terminals 311 arranged in a principal surface 301 on which the electronic device 10 on the base 30 is mounted and a resin member 50 arranged so as to cover the conductive wires 11. The sizes of the typical electronic device 10 and the typical electronic component 100 in the Z direction are smaller than those in the X and Y directions, and the electronic device 10 and the electronic component 100 each have a substantially flat plate shape.

The electronic device 10 is formed on a semiconductor substrate made of silicon, germanium, or the like. The semiconductor substrate on which the electronic device 10 is formed may be a single-crystal or polycrystalline substrate. The electronic device 10 includes an insulating layer, a wiring layer, and a protective layer formed on the semiconductor substrate.

The principal surface 101 of the electronic device 10 has a detection region 1 in which pixels are arranged and a peripheral region 2 arranged on the outside of the detection region 1. If, for example, the electronic component 100 is a radiation detector, pixels for detecting radiation are arranged in the detection region 1, and a circuit and the like for operating the detection region 1 are arranged in the peripheral region 2. Typically, the detection region 1 is located in the center of the principal surface 101 of the electronic device 10, and the peripheral region 2 is located on the periphery of the detection region 1. The principal surface 101 of the electronic device 10 can be a surface on which radiation enters.

The radiation detected by the electronic device 10 may be electromagnetic waves or particle rays. The electromagnetic waves may be light rays such as infrared rays, visible rays, or ultraviolet rays, electric waves such as microwaves, or ionizing radiation such as X-rays or gamma rays. The particle rays include alpha rays, beta rays, electron beams, neutron rays, proton beams, heavy ion rays, and meson rays. The electronic device 10 may be configured so as to properly make settings concerning the structure of the radiation detector, for example, the thickness of the semiconductor layer (semiconductor substrate) for converting radiation into electrical signals, in accordance with the transmission characteristics or absorption characteristics of radiation to be detected. The following is a description assuming that the electronic component 100 is a radiation detector.

The detection region 1 is a region provided with pixels (detection pixels) that convert the electric charge generated by the incidence of radiation into an output signal. The detection region 1 may include a structure in which a plurality of pixels including detection elements and switch elements for signal readout are arranged in a matrix pattern to form an image based on radiation. Each of the plurality of pixels may include a photodiode as a detection element like a CMOS image sensor or a CCD image sensor. As a photodiode, a PN diode or PIN diode using silicon may be used. In addition, as a photodiode, a compound semiconductor such as cadmium telluride (CdTe) or cadmium zinc telluride (CdZnTe) may be used. The photon counting principle may be used, and a device such as a single photon avalanche diode (SPAD) may be used.

The electronic device 10 (the detection region 1) may have a thickness of 10 μm or more and 100 μm or less in consideration of the balance between the prevention of crosstalk between pixels and the securement of mechanical strength. The electronic device 10 (the detection region 1) may have a thickness of 25 μm or more and 75 μm or less. Typically, the thickness of the electronic device 10 (the detection region 1) is set to 50 μm.

The peripheral region 2 is provided with peripheral circuits such as a drive circuit, a control circuit, a signal processing circuit, and an output circuit, an input terminal, and an output terminal. The drive circuit is a circuit that scans and drives each pixel in the detection region 1. The control circuit is a circuit that controls the drive timings of the drive circuit, the signal processing circuit, and the like. The control circuit can include a timing generator. The signal processing circuit processes the signals read out from the detection region 1. The signal processing circuit can include an amplification circuit and an AD conversion circuit. The output circuit converts the signal obtained by the signal processing circuit into a predetermined format and outputs it. The output circuit can include a differential transmission circuit. The input terminal is a terminal to which power and control signals are externally input. The output terminal is a terminal that outputs signals to the outside. As the input and output terminals, the plurality of terminals 111 are provided in the peripheral region 2 of the principal surface 101 of the electronic device 10, as shown in FIGS. 2 and 3. The terminals 111 are configured to be electrically connected to the terminals 311 arranged in the principal surface 301 of the base 30 (to be described later).

The support member 20 has a principal surface 201 facing the principal surface 102 of the electronic device 10, a principal surface 202 on the opposite side to the principal surface 201, and a side surface 204 connecting the principal surface 201 to the principal surface 202. In an orthogonal projection to the principal surface 102 of the electronic device 10, the support member 20 has an opening in a portion overlapping the detection region 1. On the other hand, in the electronic device 10, part of the peripheral region 2 of the principal surface 102 faces the support member 20. Likewise, in an orthogonal projection to the principal surface 102 of the electronic device 10, the base 30 has an opening in a portion overlapping the detection region 1. On the other hand, in the electronic device 10, part of the peripheral region 2 of the principal surface 102 faces the base 30 via the support member 20.

As shown in FIGS. 2 and 3, in a region where the principal surface 102 of the electronic device 10 faces the principal surface 201 of the support member 20, a coupling member 40A is arranged to couple the electronic device 10 to the support member 20. In addition, in a region where the principal surface 202 of the support member 20 faces the principal surface 301 of the base 30, a coupling member 40B is arranged to couple the support member 20 to the base 30. As the coupling members 40A and 40B, for example, an adhesive agent may be used. Alternatively, as the coupling members 40A and 40B, for example, a die attach film (DAF) or double-coated tape may be used. The same member or different members may be used for the coupling members 40A and 40B. In the region where the principal surface 102 of the electronic device 10 faces the principal surface 201 of the support member 20, the facing surfaces may not be entirely coupled to each other with the coupling member 40A. Likewise, in the region where the principal surface 202 of the support member 20 faces the principal surface 301 of the base 30, the facing surfaces may not be entirely coupled to each other with the coupling member 40B. In the respective regions, at least parts of these faces may be coupled to each other as long as the coupling strength between the electronic device 10 and the support member 20 and between the support member 20 and the base 30 is strong enough as the electronic component 100.

The support member 20 is arranged between the electronic device 10 and the base 30 and functions to secure the mechanical strength of the electronic device 10. Although described in detail later, in general, the base 30 can be formed by using a material different from the electronic device 10. As described above, when the electronic device 10 that is as thin as 10 μm or more and 100 μm or less is directly coupled to the base 30 having the opening portion like that shown in FIG. 1B, the electronic device 10 may be damaged by stress caused by the linear expansion coefficient difference. Accordingly, although the material for the support member 20 may be a semiconductor, an insulator, or a conductor, the material needs to have sufficient rigidity to support the electronic device 10. For example, in order to reduce the stress between the electronic device 10 and the support member 20, the support member 20 may be formed from the same material as that for the semiconductor substrate on which the electronic device 10 is formed. For example, if the electronic device 10 is formed on a silicon substrate, the support member 20 may be formed from silicon. If the electronic device 10 is formed on a germanium substrate, the support member 20 may be formed from germanium.

The thickness of the support member 20 may be 100 μm or more or 300 μm or more for the securement of the mechanical strength. For example, if silicon is used for the support member 20, the thickness of the support member 20 can be set to 700 μm or more and 800 μm or less, which are standard thicknesses of 8-inch and 12-inch wafers generally used as silicon substrates. It is possible to easily prepare the support member 20 by cutting out the support member 20 from a standard wafer. As described above, the thickness of the support member 20 may be 100 μm or more and 800 μm or less. In the electronic component 100, the electronic device 10 can be thinner than the support member 20. However, the invention is not limited to this, and different materials may be used to form the electronic device 10 and the support member 20. If different materials are used for the support member 20 and the electronic device 10, the support member 20 properly cut in a proper size can be used as along as the electronic device 10 can be supported.

The base 30 is a substrate on which electrical circuits that implement various functions are mounted and can be called a package on which the electronic device 10 is mounted via the support member 20. The specific functions include a function of supplying control signals and power to the electronic device 10, a function of processing the signals output from the electronic device 10, a function of storing signals, and a function of transmitting signals to an external computer and a network.

The base 30 can be formed by metallic molding, cutting work, plate member stacking, or the like. The base 30 may be an insulator for electric connection to the support member 20. In addition, from the viewpoint of mechanical strength, the base 30 may be a rigid substrate such as a glass epoxy substrate, a composite substrate, a glass composite substrate, a bakelite substrate, or a ceramic substrate. For example, as the base 30, a ceramic substrate or glass epoxy substrate is used. If the base 30 is a ceramic substrate, the base may be a ceramic multilayer. The following may be used as ceramic materials: silicon carbide, aluminum nitride, sapphire, alumina, silicon nitride, cermet, yttria, mullite, forsterite, cordierite, zirconia, steatite, and the like.

The base 30 includes a conductor layer 313 between the principal surface 301 on which the electronic device 10 is mounted and a principal surface 302 on the opposite side to the principal surface 301. As shown in FIGS. 2 and 3, the conductor layer 313 may include a plurality of layers. The different conductor layers 313 are connected to each other with conductive members 312. Of the conductor layers 313, the conductor layer 313 that is electrically connected to the terminal 111 provided in the principal surface 101 of the electronic device 10 via the conductive wire 11 and is provided in the principal surface 301 of the base 30 is called the terminal 311. In addition, of the conductor layers 313, the conductor layer 313 for connecting the electronic component 100 provided on the principal surface 301 or the principal surface 302 of the base 30 to the outside is called a terminal 314. For example, the terminal 311 and the terminal 314 corresponding thereto can be electrically connected to each other via the conductor layer 313 or the conductive member 312. The terminals 314 for electrical connection to an external circuit may be arranged for both the principal surface 301 and the principal surface 302 of the base 30 or the terminal 314 may be arranged for only the principal surface 301 or the principal surface 302 of the base 30.

The resin member 50 is arranged around the conductive wire 11 so as to completely cover the conductive wires 11. The resin member 50 is also formed on part of each of the electronic device 10, the coupling members 40A and 40B, the support member 20, and the base 30 so as to cover the conductive wires 11. For example, as shown in FIGS. 2 and 3, the resin member 50 continuously covers from the terminal 111 of the electronic device 10 to the terminal 311 of the base 30 through the side surface 204 of the support member 20. That is, the resin member 50 covers the side surface 204 of the support member 20. As shown in FIG. 1B, in an orthogonal projection to the principal surface 102 of the electronic device 10, the resin member 50 may be arranged so as to surround the outer edge of the support member 20. On the other hand, the presence of the resin member 50 in the detection region 1 of the electronic device 10 can affect the image obtained in the detection region. Accordingly, the resin member 50 can be formed within the peripheral region 2. In addition, as shown in FIGS. 2 and 3, the resin member 50 is formed so as not to cover the terminals 314 connecting the electronic component 100 to the outside.

Examples of materials for the resin member 50 are an epoxy-based resin, an acrylic-based resin, a silicone-based resin, and a vinyl-based resin. A suitable resin may be selected as the resin member 50 in consideration of the filing characteristics and fluidity of resins and the twists of the conductive wires 11. A dam member (not shown) may be arranged for the principal surface 101 of the electronic device 10 as needed to suppress the inflow of the resin member 50 into the detection region 1.

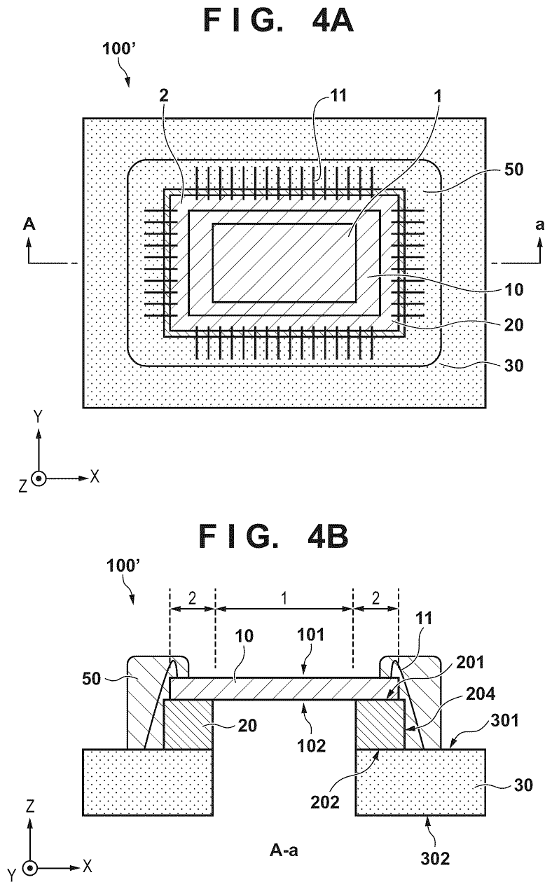

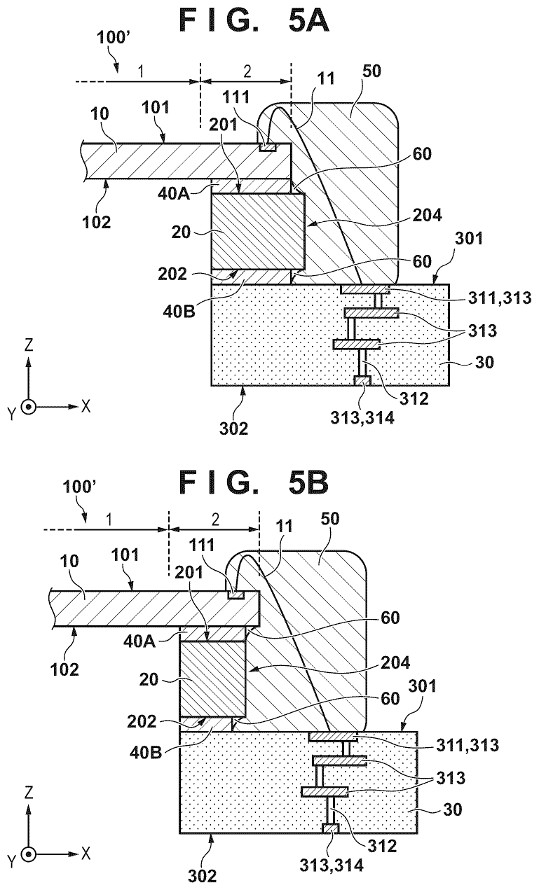

The shape of the support member 20 will be described in more detail with reference to FIGS. 2 and 3 showing the arrangement of the electronic component 100 according to this embodiment and FIGS. 4A, 4B, 5A, and 5B showing the arrangement of an electronic component 100′ according to a comparative example. In the arrangement shown in FIG. 2, the support member 20 includes a chamfered portion 203 formed by chamfering a portion between the principal surface 201 and the side surface 204. In the arrangement shown in FIG. 3, the support member 20 is arranged with chamfered portions 203 formed by chamfering both portions between the principal surface 201 and the side surface 204 and between the principal surface 202 and the side surface 204. Although not shown in FIGS. 2 and 3, the support member 20 may have a chamfered portion between the principal surface 202 and the side surface 204 and may not have a chamfered portion between the principal surface 201 and the side surface 204. That is, the support member 20 may include the chamfered portion 203 formed by chamfering a portion between the side surface 204 and at least one of the principal surface 201 and the principal surface 202. In an orthogonal projection to the principal surface 102 of the electronic device 10, as shown in FIG. 1A, the chamfered portion 203 may be arranged so as to surround the outer edge of the support member 20.

FIGS. 4A and 4B are schematic views showing an example of the arrangement of the electronic component 100′ according to the comparative example. FIG. 4A is a plan view showing an example of the arrangement of the electronic component 100. FIG. 4B is a sectional view taken along A-a shown in FIG. 4A. FIGS. 5A and 5B each are an enlarged sectional view of a right portion of the sectional view shown in FIG. 4B. The electronic component 100′ according to the comparative example differs from the electronic component 100 according to this embodiment shown in FIGS. 2 and 3 in the shape of a support member 20. More specifically, the electronic component 100′ differs from the electronic component 100 according to the embodiment in that a portion between a principal surface 201 and a side surface 204 and a portion between a principal surface 202 and the side surface 204 are not chamfered.

FIG. 5A shows a case where the outer edge of the support member 20 is arranged on the outside of the outer edge of an electronic device 10 due to the influences of outer shape tolerance and mounting accuracy. FIG. 5B shows a case where the outer edge of the support member 20 is arranged on the inside of the outer edge of the electronic device 10. In the arrangement shown in FIG. 5A, in forming a resin member 50, an air gap (air bubble) 60 that is not covered with the resin member 50 may be formed on a principal surface 201 of the support member 20 which is present on the outside of the outer edge of the electronic device 10. Consider a case where the outer edge of the support member 20 is arranged on the outside of the outer edge of a coupling member 40B arranged between a principal surface 202 of the support member 20 and a principal surface 301 of a base 30. In this case, the air gap (air bubble) 60 that is not covered with the resin member 50 may be formed below the principal surface 202 of the support member 20 which is present on the outside of the outer edge of the coupling member 40B. In the arrangement shown in FIG. 5B as well, the air gap (air bubble) 60 that is not covered with the resin member 50 may be formed below a principal surface 102 of the electronic device 10 which is present on the outside of the outer edge of the support member 20. The case shown in FIG. 5A applies to the case concerning the lower side of the support member 20 (the base 30 side). That is, if a discontinuous portion such as a stepped portion or gap occurs between the electronic device 10 and the support member 20 or between the support member 20 and the base 30, the resin may not completely permeate the discontinuous portion to cause the air gap (air bubble) 60 in the resin. In this case, the discontinuous portion is a portion that is not continuously flat. The air gap (air bubble) 60 tends to be formed in a region having a right angle or nearly right angle such as a stepped portion between members.

In contrast to this, as shown in FIGS. 2 and 3, the electronic component 100 according to this embodiment is provided with the chamfered portions 203 formed by chamfering the portions between the principal surfaces 201 and 202 of the support member 20 and the side surface 204. This makes it difficult to form a region having a right angle or nearly right angle such as a stepped region between members. As a result, it is possible to suppress the occurrence of the air gap (air bubble) 60 in the resin member 50. A portion between the principal surface 202 of the support member 20 and the base 30 is a gap that can be caused by the coupling member 40B and is a narrow space, the chamfered portion 203 widens the inlet of the space. This makes it easy for the resin member 50 to permeate and hence provides more effective suppression of the air gap (air bubble) 60.

As shown in FIG. 2, the chamfered portion 203 may be formed only between the principal surface 201 of the support member 20 and the side surface 204. In addition, the chamfered portion 203 may be formed only between the principal surface 202 of the support member 20 and the side surface 204 in consideration of a gap between the principal surface 202 of the support member 20 and the base 30. However, as shown in FIG. 3, arranging the chamfered portions 203 both between the principal surface 201 of the support member 20 and the side surface 204 and between the principal surface 202 and the side surface 204 can suppress the occurrence of the air gap (air bubble) 60 on both sides and provide more effective results.

In an orthogonal projection to the principal surface 102 of the electronic device 10, the chamfered portion 203 may be arranged on the outside of the outer edge of the electronic device 10. Arranging the chamfered portion 203 on the outside of the outer edge of the electronic device 10 will prevent a gap caused by the chamfered portion 203 from being formed between the electronic device 10 and the support member 20. This makes it possible to suppress the occurrence of the air gap (air bubble) 60 between the electronic device 10 and the support member 20 in forming the resin member 50.

As described above, in forming the resin member 50, the occurrence of the air gap (air bubble) 60 in the resin member 50 is suppressed. In using the electronic component 100, for example, using the electronic device 10 under vacuum, the air gap (air bubble) 60 may expand. The expansion of the air gap (air bubble) 60 can lead to damage to the thin electronic device 10, peeling of the coupling members 40A and 40B, displacement of the electronic device 10 and the support member 20 due to peeling of the coupling members 40A and 40B, disconnection of the conductive wires 11, and damage to the electronic component 100 such as damage to the base 30. Suppressing the occurrence of the air gap (air bubble) 60 in forming the resin member 50 can suppress damage to the electronic component 100 and improve the reliability of the electronic component 100.

Although the size of the chamfered portion 203 is not specifically limited, the terminal 111 of the electronic device 10 may be arranged on the inside of the chamfered portion 203 in an orthogonal projection to the principal surface 102 of the electronic device 10. If the space caused by the chamfered portion 203 is present on the inside of the terminal 111, in a step of connecting the conductive wire 11 to the terminal 111, the connection reliability of the terminal 111 deteriorates due to a load or abnormal transmission of ultrasonic waves. For this reason, the chamfered portion 203 is not arranged below the terminal 111 of the electronic device 10 but the principal surface 201 of the support member 20 is arranged.

In forming the chamfered portions 203 both between the principal surface 201 of the support member 20 and the side surface 204 and between the principal surface 202 and the side surface 204, the side surface 204 is left without being chamfered. This is because if the side surface 204 is not arranged, the support member 20 will have a sharp outer edge, which may cause a crack or the like in the support member 20 in grasping the support member 20 to couple the electronic device 10 to the support member 20.

The shape of the chamfered portion 203 may be, for example, that obtained by chamfering at 45°. Alternatively, for example, the shape of the chamfered portion 203 may be that obtained by chamfering at an acute or obtuse angle other than 45°. If, however, the chamfering angle is extremely acute or obtuse (for example, 10° or less or 80° or more with respect to the side surface 204 of the support member 20), a shape having a nearly right angle is generated as in the comparative example described above, resulting in difficulty in obtaining the above effect. Accordingly, the chamfered portion 203 may have a surface having an angle of 10° or more and 80° or less with respect to the side surface 204 of the support member 20. In addition, the chamfered portion 203 may have a surface having an angle of 30° or more and 60° or less with respect to the side surface 204 of the support member 20.

The chamfered portion 203 may be formed by using, for example, a physical process of polishing or cutting. Alternatively, for example, the chamfered portion 203 may be formed by a process using a chemical agent such as etching. In performing etching using a chemical agent, using a chemical that smooths the surface of the chamfered portion 203 after the process facilitates obtaining the effect of suppressing the occurrence of the air gap (air bubble) 60.

In this manner, the chamfered portions 203 are arranged between the principal surfaces 201 and 202 of the support member 20 and the side surface 204. This suppresses the occurrence of the air gap (air bubble) 60 in the resin member 50 in forming the resin member 50. This suppresses damage to the electronic component 100 due to the air gap (air bubble) 60 in the resin member 50. As a result, the reliability of the electronic component 100 can be improved.

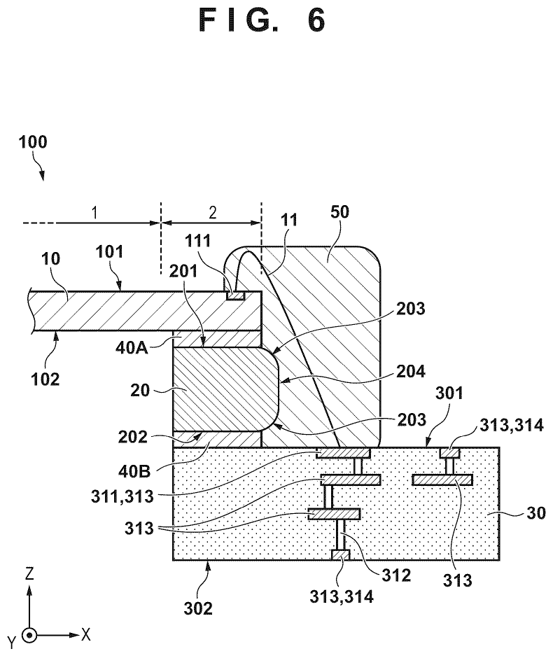

FIG. 6 is a view showing a modification of the support member 20 shown in FIGS. 2 and 3. In the arrangement shown in FIGS. 2 and 3, the chamfered portion 203 has a planar shape. However, the shape of the chamfered portion 203 is not limited to this. As shown in FIG. 6, the chamfered portion 203 may have an R-chamfered shape. As shown in FIG. 6, both the portions between the principal surface 201 of the support member 20 and the side surface 204 and between the principal surface 202 and the side surface 204 may be R-chamfered. Alternatively, for example, the portion between the side surface 204 and one of the principal surfaces 201 and 202 of the support member 20 may be R-chamfered. Alternatively, a combination of an R-chamfered shape and the above planar chamfered shape may be used.

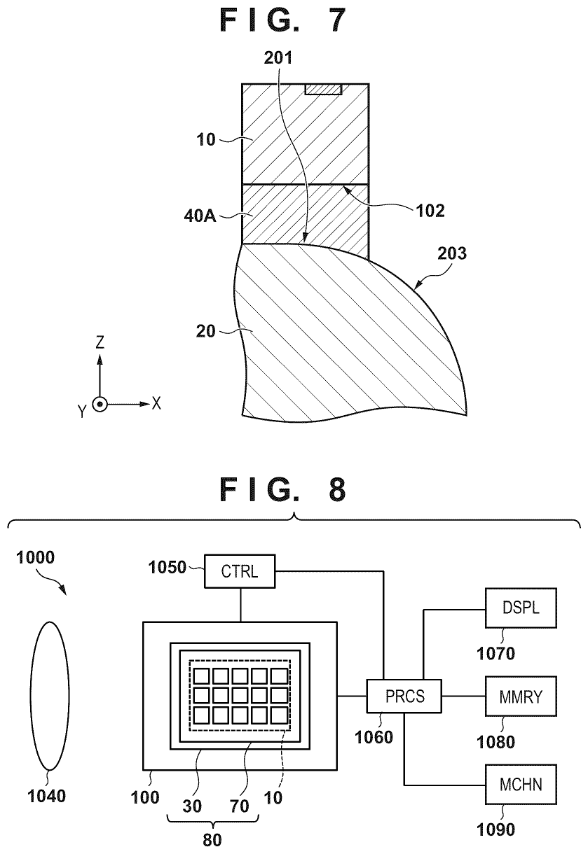

FIG. 7 is an enlarged sectional view of a portion near the coupling region between the electronic device 10 and the support member 20. Since the chamfered portion 203 has an R-chamfered shape, the angle gradually changes from the principal surface 201 of the support member 20 to the side surface 204 as compared with a C-chamfered shape. Accordingly, when the coupling member 40A extends from the principal surface 201 to part of the chamfered portion 203, a portion of the coupling member 40A which overlaps the chamfered portion 203 gradually increases in thickness. If the thickness of the coupling member 40A acutely changes, a gap may occur between the coupling member 40A and the principal surface 102 of the electronic device 10 or between the coupling member 40A and the support member 20. If a gap occurs between the coupling member 40A and the principal surface 102 of the electronic device 10 or between the coupling member 40A and the support member 20, the gap can be a factor that causes the air gap (air bubble) 60 in forming the resin member 50. In contrast to this, as shown in FIG. 7, gradually increasing the thickness of the portion of the coupling member 40A which overlaps the chamfered portion 203 will suppress the occurrence of a gap between the coupling member 40A and the principal surface 102 of the electronic device 10 or between the coupling member 40A and the support member 20. That is, this makes it possible to further increase the reliability (adhesiveness) of the coupling between the principal surface 102 of the electronic device 10 and the principal surface 201 of the support member 20. In addition, this prevents the occurrence of the air gap (air bubble) 60 in forming the resin member 50. Consequently, it is possible to suppress damage to the electronic component 100 due to the air gap (air bubble) 60 in the resin member 50 and improve the reliability of the electronic component 100.

Equipment 1000 including the electronic component 100, which is shown in FIG. 8, will be described in detail below. The electronic device 10 is accommodated in a package 80 and mounted on the equipment 1000. In the arrangement shown in FIG. 8, the electronic device 10 is a device that detects radiation. The electronic component 100 can include the package 80 including the base 30 to which the electronic device 10 is fixed and a lid body 70 such as glass facing the electronic device 10. As described above, the package 80 can be provided with joining members such as the conductive wires 11 and bumps that connect the terminals 311 arranged in the base 30 to the terminals 111 such as pad electrodes provided in the electronic device 10.

The equipment 1000 can include at least one of an optical apparatus 1040, a control apparatus 1050, a processing apparatus 1060, a display apparatus 1070, a storage apparatus 1080, and a mechanical apparatus 1090. The optical apparatus 1040 is implemented by, for example, a lens, a shutter, and a mirror. The control apparatus 1050 controls the electronic device 10. The control apparatus 1050 is, for example, a semiconductor apparatus such as an ASIC.

The processing apparatus 1060 processes a signal output from the electronic device 10. The processing apparatus 1060 is a semiconductor apparatus such as a CPU or an ASIC for forming an Analog Front End (AFE) or a Digital Front End (DFE). The display apparatus 1070 is an EL display apparatus or a liquid crystal display apparatus that displays information (image) obtained by the electronic device 10. The storage apparatus 1080 is a magnetic device or a semiconductor device that stores the information (image) obtained by the electronic device 10. The storage apparatus 1080 is a volatile memory such as an SRAM or a DRAM, or a nonvolatile memory such as a flash memory or a hard disk drive.

The mechanical apparatus 1090 includes a moving or propulsion unit such as a motor or an engine. In the equipment 1000, the signal output from the electronic device 10 is displayed on the display apparatus 1070 or transmitted to an external apparatus by a communication apparatus (not shown) included in the equipment 1000. Hence, the equipment 1000 may further include the storage apparatus 1080 and the processing apparatus 1060 in addition to the memory circuits and arithmetic circuits included in the electronic device 10. The mechanical apparatus 1090 may be controlled based on the signal output from the electronic device 10.

In addition, the equipment 1000 is suitable for electronic equipment such as an information terminal (for example, a smartphone or a wearable terminal) which has a shooting function or a camera (for example, an interchangeable lens camera, a compact camera, a video camera, or a monitoring camera). The mechanical apparatus 1090 in the camera can drive the components of the optical apparatus 1040 in order to perform zooming, an in-focus operation, and a shutter operation. Alternatively, the mechanical apparatus 1090 in the camera can move the electronic device 10 in order to perform an anti-vibration operation.

Furthermore, the equipment 1000 can be transportation equipment such as a vehicle, a ship, or an airplane. The mechanical apparatus 1090 in the transportation equipment can be used as a moving apparatus. The equipment 1000 as the transportation equipment is suitable for an apparatus that transports the electronic device 10 or an apparatus that uses a shooting function to assist and/or automate driving (steering). The processing apparatus 1060 for assisting and/or automating driving (steering) can perform, based on the information obtained by the electronic device 10, processing for operating the mechanical apparatus 1090 as a moving apparatus. Alternatively, the equipment 1000 may be medical equipment such as an endoscope, measurement equipment such as a distance measurement sensor, analysis equipment such as an electron, microscope office equipment such as a copy machine, or industrial equipment such as a robot.

According to the present disclosure, a technique advantageous in suppressing damage to the electronic component can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-156527, filed Sep. 21, 2023, which is hereby incorporated by reference herein in its entirety.

What is claimed is:

1. An electronic component comprising:
a base;
an electronic device including a first principal surface having a region facing the base and a second principal surface on an opposite side to the first principal surface;
a support member arranged between the electronic device and the base;
a conductive wire configured to connect a first terminal arranged in the second principal surface to a second terminal arranged in a third principal surface on which the electronic device of the base is mounted; and
a resin member arranged so as to cover the conductive wire,
wherein the support member includes a fourth principal surface facing the first principal surface, a fifth principal surface on an opposite side to the fourth principal surface, and a side surface connecting the fourth principal surface to the fifth principal surface,
the resin member covers at least part of the side surface, and
the support member includes a chamfered portion obtained by chamfering a portion between the side surface and at least one of the fourth principal surface and the fifth principal surface.

2. The electronic component according to claim 1, wherein the support member has chamfered portions both between the fourth principal surface and the side surface and between the fifth principal surface and the side surface.

3. The electronic component according to claim 1, wherein in an orthogonal projection to the first principal surface, the first terminal is arranged on an inside of the chamfered portion.

4. The electronic component according to claim 1, wherein in an orthogonal projection to the first principal surface, the chamfered portion is arranged on an outside of an outer edge of the electronic device.

5. The electronic component according to claim 1, wherein the chamfered portion has a surface having an angle of not less than 30° and not more than 60° with respect to the side surface.

6. The electronic component according to claim 1, wherein the chamfered portion has an R-chamfered shape.

7. The electronic component according to claim 1, wherein the chamfered portion is arranged so as to surround an outer edge of the support member in an orthogonal projection to the first principal surface.

8. The electronic component according to claim 1, wherein the second principal surface includes a detection region in which a pixel is arranged and a peripheral region arranged on an outside of the detection region, and
in an orthogonal projection to the first principal surface, the support member has an opening in a portion overlapping the detection region.

9. The electronic component according to claim 8, in the orthogonal projection to the first principal surface, wherein the base has an opening in a portion overlapping the detection region.

10. The electronic component according to claim 1, wherein the electronic device is formed on a semiconductor substrate, and
the support member uses the same material as the semiconductor substrate.

11. The electronic component according to claim 1, wherein the electronic device is thinner than the support member.

12. The electronic component according to claim 1, wherein the electronic device has a thickness of not less than 10 μm and not more than 100 μm.

13. The electronic component according to claim 1, wherein the support member has a thickness of not less than 100 μm and not more than 800 μm.

14. The electronic component according to claim 1, wherein the resin member continuously covers from the first terminal to the second terminal through the side surface.

15. The electronic component according to claim 1, wherein in an orthogonal projection to the first principal surface, the resin member is arranged so as to surround an outer edge of the support member.

16. The electronic component according to claim 1, wherein the third principal surface is provided with a third terminal configured to connect the electronic component to an outside, and
the resin member does not cover the third terminal.

17. Equipment comprising:
the electronic component according to claim 1; and
a processing apparatus configured to process a signal output from the electronic component.
